(19) United States
(12) Patent Application Publication
(10) Pub. No.: US 2022/0336196 A1
(43) Pub. Date: Oct. 20, 2022

(54) ABNORMALITY DETERMINATION SYSTEM AND ABNORMALITY DETERMINATION METHOD FOR PLASMA TREATMENT

(71) Applicant: Panasonic Intellectual Property Management Co., Ltd., Osaka (JP)

(72) Inventor: Masaru NONOMURA, Osaka (JP)

(21) Appl. No.: 17/764,640

(22) PCT Filed: Sep. 1, 2020
(86) PCT No.: PCT/JP2020/033110

§ 371 Date: Mar. 29, 2022

(30) Foreign Application Priority Data
Sep. 30, 2019 (JP) 2019-180533

(51) Int. Cl. H01J 37/32

(52) U.S. Cl. CPC H01J 37/32926; H01J 37/32935; H01J 2237/0206

(57) ABSTRACT

Disclosed is an abnormality determination system for plasma treatment, including: a plasma treatment apparatus capable of treating, based on a recipe, a plurality of workpieces at a time; a sensor that obtains at least one monitoring data relating to the workpieces and the plasma treatment apparatus that is performing plasma treatment; a storage unit that stores a threshold that is set according to a first treatment mode including the number and the type of the workpieces; and a determination unit that determines, based on the monitoring data and the threshold, whether or not there is an abnormality in the plasma treatment.

### TECHNICAL FIELD

The present invention relates to an abnormality determination system and an abnormality determination method for plasma treatment.

### BACKGROUND ART

There are known plasma treatment techniques for performing surface modification and cleaning of wafers and substrates by using plasma in a semiconductor manufacturing process. In order to perform appropriate plasma treatment, PTL 1 teaches monitoring a potential change induced in response to a change in plasma discharge, and determining the presence or absence of abnormal discharge from the potential change.

### CITATION LIST

### Patent Literature

[PTL 1] Japanese Laid-Open Patent Publication No. 2009-135253

### SUMMARY OF INVENTION

### Technical Problem

In plasma treatment intended for surface modification and cleaning of wafers and substrates, a plurality of workpieces or a plurality of types of workpieces may be treated at a time in order to increase the throughput. The impedance in a high-frequency circuit of a plasma treatment apparatus changes depending on the number and the type of workpieces. Furthermore, the mechanisms of occurrence of an abnormality in plasma treatment are affected by a plurality of types of factors, including, for example, the material and the shape of workpieces, conditions such as a moisture absorption state, and contamination of the plasma treatment apparatus. Therefore, it is very difficult to determine an abnormality of plasma treatment with high accuracy.

### Solution to Problem

An aspect of the present invention relates to an abnormality determination system for plasma treatment, including: a plasma treatment apparatus capable of treating, based on a recipe, a plurality of workpieces at a time; a sensor that obtains at least one monitoring data relating to the workpieces and the plasma treatment apparatus that is performing plasma treatment; a storage unit that stores a threshold that is set according to a first treatment mode including the number and the type of the workpieces; and a determination unit that determines, based on the monitoring data and the threshold, whether or not there is an abnormality in the plasma treatment.

Another aspect of the present invention relates to an abnormality determination system for plasma treatment, including: a plasma treatment apparatus capable of treating, based on a recipe, a plurality of workpieces at a time; a sensor that obtains at least one monitoring data relating to the workpieces and the plasma treatment apparatus that is performing plasma treatment; a storage unit that stores a monitoring history obtained by the sensor during plasma treatment performed in the past in a treatment mode that is the same as a first treatment mode including the number and the type of the workpieces to be plasma treated, the monitoring history corresponding to the monitoring data; and a determination unit that determines, based on a difference between the monitoring data and the monitoring history, whether or not there is an abnormality in the plasma treatment.

Still another aspect of the present invention relates to an abnormality determination method for plasma treatment, including: a plasma treatment step of performing plasma treatment for workpieces, using a plasma treatment apparatus capable of treating a plurality of workpieces at a time; a monitoring data obtaining step of obtaining at least one monitoring data relating to the workpieces and the plasma treatment apparatus that is performing plasma treatment; and a determination step of determining whether or not there is an abnormality in the plasma treatment, based on the monitoring data, and a threshold that is set according to a first treatment mode including the number and the type of the workpieces.

Yet another aspect of the present invention relates to an abnormality determination method for plasma treatment, including: a plasma treatment step of performing plasma treatment for workpieces, using a plasma treatment apparatus capable of treating a plurality of workpieces at a time; a monitoring data obtaining step of obtaining at least one monitoring data relating to the workpieces and the plasma treatment apparatus that is performing plasma treatment; a calculation step of calculating a difference between the monitoring data and a monitoring history obtained during plasma treatment performed in the past in a treatment mode that is the same as a first treatment mode including the number and the type of the workpieces to be plasma treated, the monitoring history corresponding to the monitoring data; and a determination step of determining, based on the difference, whether or not there is an abnormality in the plasma treatment.

### Advantageous Effects of Invention

According to the present invention, the accuracy of abnormality determination is improved.

While the novel features of the invention are set forth in the appended claims, the invention, both as to organization and content, will be better understood and appreciated, along with other objects and features thereof, from the following detailed description taken in conjunction with the drawings.

### BRIEF DESCRIPTION OF DRAWINGS

FIG. 1 is a flowchart showing a relationship between a flow of plasma treatment according to an embodiment of the present invention and the types of monitoring data obtained.

FIG. 2 is a block diagram showing an example of a configuration of a first abnormality determination system according to an embodiment of the present invention.

FIG. 3 is a flowchart showing an example of a first abnormality determination method according to an embodiment of the present invention.

FIG. 4 is a flowchart showing another example of the first abnormality determination method according to the embodiment of the present invention.

FIG. 5 is a flowchart showing still another example of the first abnormality determination method according to the embodiment of the present invention.

FIG. 6 is a flowchart showing yet another example of the first abnormality determination method according to the embodiment of the present invention.

FIG. 7 is a flowchart showing an example of a second abnormality determination method according to an embodiment of the present invention.

FIG. 8 is a flowchart showing another example of the second abnormality determination method according to the embodiment of the present invention.

FIG. 9 is a flowchart showing still another example of the second abnormality determination method according to the embodiment of the present invention.

FIG. 10 is a flowchart showing yet another example of the second abnormality determination method according to the embodiment of the present invention.

### DESCRIPTION OF EMBODIMENT

In the present embodiment, a threshold that is set taking into account a treatment mode specified according to the number of workpieces and the type thereof, or data (monitoring history) obtained during plasma treatment performed in the past in the same treatment mode is used for abnormality determination for plasma treatment. By using a criterion suitable for the treatment mode, the accuracy in determining whether or not there is an abnormality in plasma treatment (hereinafter may be referred to as a treatment abnormality) is improved. Accordingly, the quality of plasma treatment becomes stable, and the production of defective products is suppressed. Furthermore, this determination makes it easy to ascertain the timing of performing maintenance of the plasma treatment apparatus, such as cleaning, and replacement or repair of components. Thus, it is possible to increase the operating ratio of the plasma treatment apparatus.

That is, a first abnormality determination system according to the present embodiment includes: a plasma treatment apparatus capable of treating, based on a recipe, a plurality of workpieces at a time; a sensor that obtains at least one monitoring data relating to the workpieces and the plasma treatment apparatus that is performing plasma treatment; a storage unit that stores a threshold that is set according to a first treatment mode including the number and the type of the workpieces; and a determination unit that determines, based on the monitoring data and the threshold, whether or not there is an abnormality in the plasma treatment.

A first abnormality determination method according to the present embodiment includes: a plasma treatment step of performing plasma treatment for workpieces, using a plasma treatment apparatus capable of treating a plurality of workpieces at a time; a monitoring data obtaining step of obtaining at least one monitoring data relating to the workpieces and the plasma treatment apparatus that is performing plasma treatment; and a determination step of determining whether or not there is an abnormality in the plasma treatment, based on the monitoring data, and a threshold that is set according to a first treatment mode including the number and the type of the workpieces.

A second abnormality determination system according to the present embodiment includes: a plasma treatment apparatus capable of treating, based on a recipe, a plurality of workpieces at a time; a sensor that obtains at least one monitoring data relating to the workpieces and the plasma treatment apparatus that is performing plasma treatment; a storage unit that stores a monitoring history obtained by the sensor during plasma treatment performed in the past in a treatment mode that is the same as a first treatment mode including the number and the type of the workpieces to be plasma treated, the monitoring history corresponding to the monitoring data; and a determination unit that determines, based on a difference between the monitoring data and the monitoring history, whether or not there is an abnormality in the plasma treatment.

A second abnormality determination method according to the present embodiment includes: a plasma treatment step of performing plasma treatment for workpieces, using a plasma treatment apparatus capable of treating a plurality of workpieces at a time; a monitoring data obtaining step of obtaining at least one monitoring data relating to the workpieces and the plasma treatment apparatus that is performing plasma treatment; a calculation step of calculating a difference between the monitoring data and a monitoring history obtained during plasma treatment performed in the past in a treatment mode that is the same as a first treatment mode including the number and the type of the workpieces to be plasma treated, the monitoring history corresponding to the monitoring data; and a determination step of determining, based on the difference, whether or not there is an abnormality in the plasma treatment.

### (A1) First Abnormality Determination System

The abnormality determination system according to the present embodiment includes a plasma treatment apparatus, a sensor, a storage unit, and a determination unit. The storage unit and the determination unit are located in a server, for example. The manager who owns the server and the owner of the plasma treatment apparatus (hereinafter may be simply referred to as an apparatus) may be different from each other. The server and the apparatus are connected to each other via a computer network. The server further includes a storage unit, a calculation unit, and so forth, which will be described later.

### (Plasma Treatment Apparatus)

The plasma treatment apparatus is not particularly limited, as long as workpieces can be plasma treated. The plasma treatment apparatus includes, for example, a reaction chamber, a plasma generating part that generates plasma in the reaction chamber, a stage installed inside the reaction chamber and on which a substrate is to be placed, and a transport rail for loading and unloading workpieces into and out of the reaction chamber. The plasma generating part is composed of, for example, electrodes respectively installed at upper and lower portions of the reaction chamber, and a process gas source that supplies a plasma generating gas (process gas) into the reaction chamber. As a result of high-frequency power being supplied to the electrodes, with the process gas supplied in the reaction chamber, plasma is generated inside the reaction chamber.

In a recipe used for plasma treatment, the pressure in the interior of the reaction chamber, the type and the flow rate of the process gas, the output of the high-frequency power, the frequency of the high-frequency wave, the treatment time, and so forth are defined. The recipe is stored in the storage unit.

### (Sensor)

The sensor obtains various types of data (monitoring data) relating to the workpieces and the apparatus that is performing plasma treatment. The sensor is attached inside and/or outside of the apparatus. The monitoring data relating to the workpieces is obtained in real time during plasma treatment, or obtained after plasma treatment. The monitoring data relating to the apparatus is obtained in real time during plasma treatment. The monitoring data is stored in the storage unit.

The monitoring data is not particularly limited, and examples thereof include data relating to transport such as the driving torque of a transport arm, the load applied to the transport arm, and the movement speed of the transport arm; data relating to evacuation characteristics such as the pressure reached in the reaction chamber, the pressure decreasing rate at which the atmospheric pressure reaches a predetermined pressure, and the time required to reach the predetermined pressure, the pressure increasing rate at which a predetermined pressure reaches the atmospheric pressure, and the time required to reach the predetermined pressure, the flow rate of the process gas supplied to the reaction chamber during the treatment, the pressure inside the reaction chamber during the treatment, and the degree of opening of a pressure adjustment valve during the treatment; data relating to the discharge state such as the output of the high-frequency power supply, the treatment time, the matching position of a matching device, the load impedance of the matching device, the reflected RF wave and/or incident RF wave, the self-bias voltage (Vdc), the amplitude (Vpp) of the high-frequency voltage, the emission spectrum, the potential variation (hereinafter may be referred to as a plasma monitor waveform) between probe electrodes installed in the reaction chamber.

Data that is obtained in real time, or data that can be calculated from data obtained after plasma treatment is further included in the monitoring data. For example, the frequency of occurrence of change in voltage due to micro-arc discharge that appears in a plasma monitor waveform is also included in the monitoring data relating to the discharge state. The etching rate calculated from the film thickness of the workpieces that is measured before and after plasma treatment is also included in the monitoring data relating to the discharge state. The film thickness of the workpieces is measured with an optical interference film thickness gauge or a fluorescent X-ray film thickness gauge, for example.

It is sufficient that one or more pieces of monitoring data are obtained, and it is preferable that a plurality of pieces of monitoring data are obtained. It is desirable that at least the data relating to the discharge state is obtained. It is desirable that a plasma monitor waveform is obtained as the discharge state. In particular, it is desirable that one or more pieces of data from the data relating to the discharge state, and one or more pieces of data from the data relating to the evacuation characteristics and/or the data relating to the transport are obtained. The reason for this is that the accuracy of the abnormality determination is further improved, and the cause of the treatment abnormality can be more easily determined.

### (Workpieces)

The workpieces that are to be etched are not particularly limited. Examples thereof include a substrate for use in manufacture of electronic devices, a circuit board obtained by forming a circuit on a substrate, a mounting substrate obtained by mounting an electronic component on a circuit board, and a wafer. For example, the workpieces slide on the transport rail by being pushed by the transport arm, and are loaded into the reaction chamber or unloaded out of the reaction chamber.

The number of workpieces that are treated at a time by the plasma treatment apparatus is not particularly limited. One workpiece, or two or more workpieces are placed on the stage. In order to obtain a reference history, which will be described later, the plasma treatment apparatus may be operated with no workpiece placed on the stage. That is, the reference history also includes monitoring data obtained when the number of workpieces is 0.

### (First Treatment Mode)

The first treatment mode indicates a state in which workpieces (hereinafter referred to as real workpieces) are plasma treated, and includes the number and the type of the real workpieces. The number and the type of the real workpieces significantly affect the above-described monitoring data. Therefore, by using, as a criterion, a threshold that is set according to the treatment mode, the accuracy of the abnormality determination is improved. The first treatment mode is obtained by a first obtaining unit.

Examples of the treatment mode include, in addition to the number and the type of the real workpieces, the size and the lot number of the real workpieces, and a condition for processing performed prior to the plasma treatment. In the case where a bar code or two-dimensional code indicating the treatment mode is attached to each real workpiece, the code is read, either automatically or through an operation performed by the operator, inside the plasma treatment apparatus or up until the step in which the real workpiece is loaded into the plasma treatment apparatus. The read code is obtained as the first treatment mode by the first obtaining unit. The first treatment mode may be input to the first obtaining unit by the operator, or may be stored in advance in a storage medium. The first treatment mode obtained by the first obtaining unit is stored in the storage unit.

### (Storage Unit)

A threshold that is set according to the treatment mode is stored in the storage unit. The threshold is set for each of the above-described monitoring data, and serves as a criterion for determining whether or not there is a treatment abnormality. If the monitoring data falls outside the threshold, it is determined that there is a treatment abnormality.

The threshold is set based on data (monitoring history) relating to the apparatus and the workpieces that was obtained in the past when plasma treating the workpieces in the same first treatment mode as that used for the real workpieces, taking into account a treatment evaluation as to whether or not the plasma treatment for the workpieces was proper.

The threshold may be calculated in the calculation unit. In this case, the monitoring history is stored in the storage unit. After the first treatment mode has been obtained, the calculation unit reads out the monitoring history corresponding to the first treatment mode from the storage unit, and calculates a threshold using a predetermined algorithm that has been set taking the treatment evaluation into account. The calculated threshold is stored in the storage unit.

### (Determination Unit)

The determination unit determines, based on the monitoring data and the threshold, whether or not there is a treatment abnormality. By comparing the present data with the past data that have been obtained through treatments in the same treatment mode, it is possible to perform highly accurate abnormality determination.

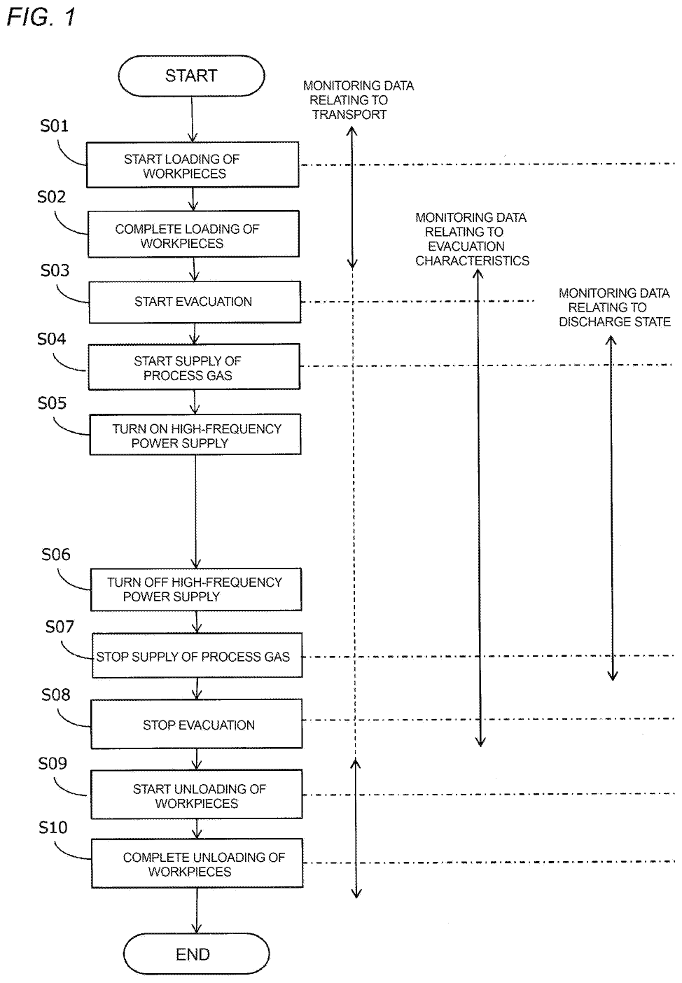

The monitoring data is obtained during a period from immediately after the start of the operation of loading the real workpieces to the end of the operation of unloading the real workpieces. The plasma treatment is performed according to the flow shown in FIG. 1, for example. FIG. 1 is a flowchart showing a relationship between the flow of plasma treatment and the types of the monitoring data obtained.

First, the operation of loading the real workpieces is started (S01). For example, the real workpieces are transferred from an external rail installed outside the plasma treatment apparatus to the transport rail installed inside the plasma treatment apparatus, and are thereafter moved on the transport rail while being pushed by the transport arm. When the real workpieces have been disposed at a predetermined position, the loading operation is completed (S02), and evacuation of the interior of the reaction chamber is started (S03). After the real workpieces have been transferred to the transport rail, the reaction chamber is sealed. The evacuation is performed until the operation of unloading the real workpieces is started, and the interior of the reaction chamber is depressurized during the plasma treatment.

When the pressure inside the reaction chamber has reached a predetermined pressure, the process gas is supplied into the reaction chamber (S04). Subsequently, a high-frequency power supply is turned on (S05), whereupon plasma is generated. Consequently, the real workpieces are plasma treated. After a predetermined time has elapsed, the high-frequency power supply is turned off (S06), whereupon the supply of the process gas is stopped (S07). Subsequently, the evacuation is stopped (S08), to increase the pressure inside the reaction chamber to the atmospheric pressure. Finally, the operation of unloading the real workpieces is started (S09). In the same manner as when being loaded, the real workpieces are moved on the transport rail while being pushed by the transport arm. After the real workpieces have been unloaded to the outside of the plasma treatment apparatus, the unloading operation is completed (S10), whereupon the plasma treatment ends.

During a period from the start (S01) to the completion (S02) of the operation of loading the real workpieces, the above-described monitoring data relating to the transport is obtained. When the reaction chamber has been sealed, the obtainment of the pressure inside the reaction chamber is started. When the evacuation is started (S03), the monitoring data relating to the evacuation characteristics is obtained.

During a period from the start (S03) to the stop (S08) of the evacuation, the above-described monitoring data relating to the discharge state is obtained, in addition to the evacuation characteristics.

Furthermore, during a period from shortly before turning on (S05) to shortly after turning off (S06) of the high-frequency power supply, a plasma monitor waveform is obtained as the monitoring data relating to the discharge state.

During a period from before turning off (S06) of the high-frequency power supply to releasing of the reaction chamber to the atmosphere, the above-described monitoring data relating to the evacuation characteristics is obtained. During a period from the start (S09) to the end (S10) of the operation of unloading the real workpieces, the above-described monitoring data relating to the transport is obtained in the same manner.

The determination unit can also determine in which of the plasma treatment apparatus, the workpieces, and the recipe the cause of the treatment abnormality lies. This makes it easy to appropriately handle the treatment abnormality, so that the operating ratio is increased, and the quality of the plasma treatment is improved.

The determination of the cause of the treatment abnormality is performed based on the type of monitoring data (hereinafter referred to as NG data) that falls outside the threshold. For example, if the NG data relates to the evacuation characteristics, a defect in an evacuation pump, a failure in sealing the reaction chamber, contamination of the interior of the reaction chamber, and the like are suspected of causing the treatment abnormality. Therefore, it is determined that the cause of the treatment abnormality in this case lies in the plasma treatment apparatus.

When the NG data relates to the discharge state, mismatching of the recipe, contamination of the interior (especially, the electrodes) of the reaction chamber, a failure of the high-frequency power supply, and a change in the shape and/or the condition (e.g., the contamination state and the moisture absorption state) of the real workpieces are suspected of causing the treatment abnormality. Therefore, it is determined that the cause of the treatment abnormality in this case lies in the recipe, a particular portion (specifically, a component inside the high-frequency circuit or the reaction chamber) of the plasma treatment apparatus, or the real workpieces.

When the NG data relates to the transport, positional displacement of the transport rail, deformation and positional displacement of the workpiece, excessive absorption of moisture by the workpieces, contamination of the sliding surface of the workpieces, and the like are suspected of causing the treatment abnormality. Therefore, it is determined that the cause of the treatment abnormality in this case lies in the apparatus or the workpieces.

It is possible to further narrow down the causes of the treatment abnormality by referring to a plurality of types of NG data. For example, when the data relating to the discharge state and the data relating to the evacuation characteristics both include NG data, it is highly likely that the cause of the treatment abnormality is contamination of the interior of the reaction chamber, rather than a failure of the apparatus.

It is possible to narrow down the causes of the treatment abnormality also by referring to monitoring data (hereinafter referred to as OK data) that falls within the threshold, in addition to the NG data. For example, when the data relating to the discharge state includes NG data, whereas the data relating to the evacuation characteristics includes OK data, it is highly likely that the cause of the treatment abnormality is a failure of a component of the apparatus, such as the high-frequency power supply, or a change in condition of the real workpieces, rather than contamination of the interior of the reaction chamber but.

For determination of the cause of the treatment abnormality, it is possible to use, in addition to the type of the NG data, monitoring data (reference history) obtained during plasma treatment performed in the past for workpieces of the same type as the real workpiece in a second treatment mode that is different only in the number of workpieces to be treated. This makes it possible to determine whether or not the cause of the treatment abnormality lies in the workpiece. The reference history is stored in the storage unit, for example.

If the frequency and the extent of the abnormality included in the monitoring data in the NG data are not significantly different from the frequency and the extent of the abnormality included in the reference history, it can be said that the treatment abnormality is not dependent on the number of workpieces. That is, it can be determined that the cause of the treatment abnormality lies in the plasma treatment apparatus or the recipe. On the other hand, if the frequency and the extent of the abnormality included in the monitoring data in the NG data are significantly different from the frequency and the extent of the abnormality included in the reference history, it can be said that the treatment abnormality is dependent on the number of workpieces. That is, it can be determined that the cause of the treatment abnormality lies in the workpieces. The criterion for determining whether or not the treatment abnormality is dependent on the number of workpieces is set as appropriate according to the NG data.

In addition, the determination unit can further determine, based on the type of the NG data, whether or not to stop the plasma treatment. For example, when the NG data includes the data relating to the transport, the plasma treatment apparatus or the workpieces may be damaged if the plasma treatment is continued. Therefore, the plasma treatment is stopped in such as case.

In other cases, the plasma treatment may be continued even if it is determined that there is a treatment abnormality. However, modification of the recipe is considered such that the desired plasma treatment is performed. In the case where the plasma treatment can be normalized by modifying the recipe, the determination unit determines that the recipe needs to be modified. For example, when the NG data is the pressure decreasing rate inside the reaction chamber, the calculation unit generates a new recipe with different set values for the evacuation time and the pressure at the time of turning on the high-frequency power supply. A predetermined algorithm is used for the generation of the recipe.

The new recipe is stored in the storage unit, and is fed back to the plasma treatment apparatus. The real workpieces are treated based on the new recipe.

Whether or not the recipe needs to be modified may be determined taking into account a follow-up result (evaluation information) as to whether or not the real workpieces were properly plasma treated. This improves the accuracy of determining whether or not the recipe needs to be modified. If the actual treatment is evaluated to be proper, it is determined that the recipe does not need to be modified even if it is determined that there is a treatment abnormality. On the other hand, if the actual treatment is evaluated to be improper, and the plasma treatment can be normalized by modifying the recipe, it is determined that the recipe needs to be modified. In the latter case, a new recipe is generated and fed back to the plasma treatment apparatus.

If the plasma treatment cannot be normalized even by modifying the recipe, or the recipe to be modified deviates from a modifiable range, it is determined that the recipe does not need to be modified. In this case, the determination unit can determine whether or not maintenance of the plasma treatment apparatus is needed. Whether or not maintenance is needed is also determined based on the type of the NG data. For example, when the NG data includes the data relating to the discharge state, the determination unit determines that maintenance is needed.

Whether or not the maintenance is needed may also be determined taking into account the above-described evaluation information. This improves the accuracy of determining whether or not the maintenance is needed. If the actual treatment is evaluated to be proper, it is determined that there is no need for maintenance, even if it is determined that there is a treatment abnormality. This can reduce the maintenance frequency, so that the operating ratio can be increased. On the other hand, if the actual treatment is evaluated to be improper, it is determined that the maintenance is needed. In the latter case, the maintenance timing or the degree of progress of a defect is calculated by the calculation unit, and a component (hereinafter referred to as a replacement component) that has caused the abnormality is further specified. A predetermined algorithm is used for the calculation or the like of the maintenance timing. This makes it possible to perform maintenance at an optimal timing, so that the operating ratio can be increased.

Whether or not the threshold needs to be modified may be performed by the determination unit. Whether or not the threshold needs to be modified is determined based on the above-described evaluation information. For example, if the actual treatment is evaluated to be improper despite that it is determined that there is no treatment abnormality, the threshold is modified such that the condition is more stringent. Conversely, if the actual treatment is evaluated to be proper despite that it is determined that there is a treatment abnormality, the threshold is modified such that the condition is relaxed. This reduces the frequency with which the apparatus is stopped as a result of abnormality determination, so that the operating ratio is increased, and the accuracy of abnormality determination is further improved. Anew threshold is generated by the calculation unit, and is stored in the storage unit. The determination of a treatment abnormality is performed based on the new threshold.

### (Notification Unit)

A notification indicating that maintenance of the plasma treatment apparatus is needed is provided by the notification unit.

The notification unit includes, for example, a display unit for displaying the maintenance timing or the like, or a signal output unit for transmitting the maintenance timing to a host system. The notification unit notifies, using display or an output signal, the maintenance timing or the like to the manager of the server, or the owner or operator of the apparatus. The notification unit may be installed in the plasma treatment apparatus, or may be installed in the server that includes the determination unit. Upon receiving the maintenance notification, the owner or operator of the apparatus cleans the interior of the reaction chamber, or performs replacement or the like of the component. This allows for predictive maintenance of the plasma treatment apparatus, resulting in an increase in operating ratio.

### (Ordering Unit)

The abnormality determination system may further include an ordering unit that automatically orders the replacement component. For example, the maintenance timing or the like is notified by the notification unit, and the replacement component is ordered by the ordering unit. This allows for predictive maintenance of the plasma treatment apparatus, resulting in an increase in operating ratio.

### (Second Obtaining Unit)

The above-described evaluation information is obtained by an obtaining unit (second obtaining unit). The evaluation information may be obtained by analyzing workpieces immediately after the workpieces have been plasma treated, or analyzing workpieces that have been subjected to another step subsequent to the plasma treatment. The evaluation information may be obtained by further analyzing the frequency of occurrence of a failure (e.g., wire bonding failure) caused by workpieces that have been subjected to another step. Examples of the steps subsequent to the plasma treatment include wire bonding, reflow, molding, and resin application. The evaluation information may be input to the second obtaining unit by the operator, for example. The input evaluation information is stored in the storage unit.

Conventionally, there has been no specific criterion for quantitatively evaluating a defect such as contamination or degradation of the plasma treatment apparatus. For this reason, the quality control and the maintenance of the plasma treatment apparatus are performed by periodically carrying out maintenance such as cleaning and replacement of components. However, contamination of the plasma treatment apparatus significantly depends on workpieces that are treated, and the treatment condition. Moreover, the apparatus undergoes changes and degradation over time. Accordingly, the periodical maintenance may not be carried out in time, resulting in the occurrence of a treatment abnormality. Many of treatment abnormalities are found as a result of a defect occurring in the above-described subsequent steps. That is, it takes a long time for a treatment abnormality to be recognized since it has occurred, so that the yield is likely to be reduced. In addition, measures are taken after a defect has actually occurred in the apparatus, so that the maintenance cost is likely to increase, or the operation stop period is likely to be increased. On the other hand, unnecessary periodical maintenance may lead to a reduction in the operating ratio of the apparatus. According to the present embodiment, it is possible to perform maintenance at an appropriate timing, and prepare a replacement component at an appropriate timing, so that a production plan can be easily arranged, and the cost and the period can be reduced.

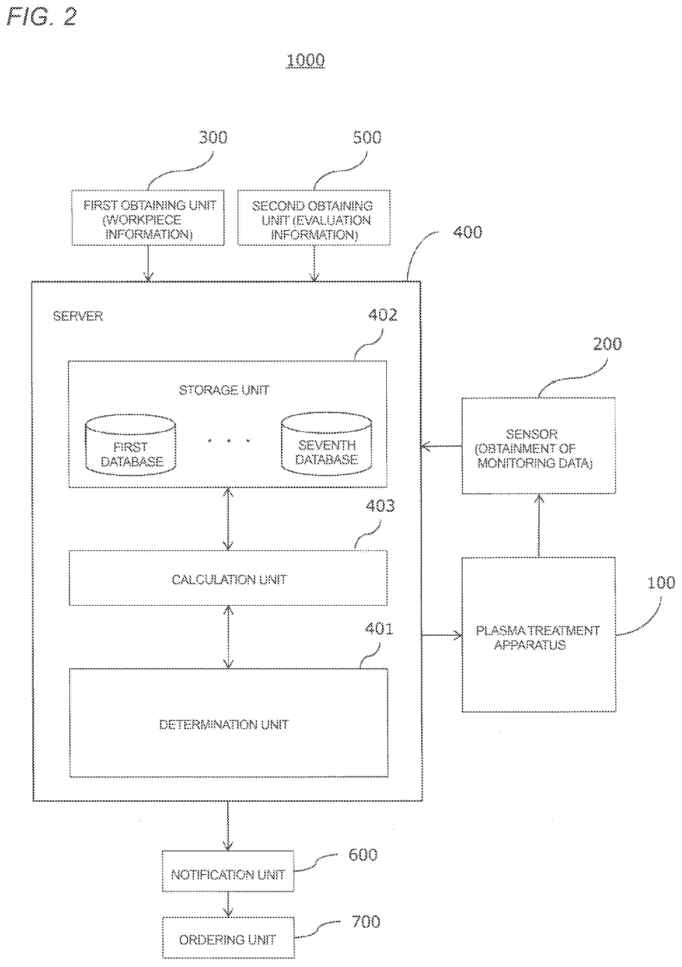

FIG. 2 is a block diagram showing an example of a configuration of an abnormality determination system according to the present embodiment.

A first abnormality determination system 1000 includes a plasma treatment apparatus 100, a sensor 200, a first obtaining unit 300, a server 400, a second obtaining unit 500, a notification unit 600, and an ordering unit 700. The server 400 includes a determination unit 401, a storage unit 402, and a calculation unit 403. The storage unit 402 includes a first database in which treatment modes are stored, a second database in which thresholds are stored, a third database in which recipes are stored, a fourth database in which monitoring data is stored, and a fifth database in which evaluation information is stored. The storage unit 402 may further include a sixth database in which monitoring histories are stored, and a seventh database in which tolerances are stored.

The plasma treatment apparatus 100 performs, based on a recipe stored in the third database, plasma treatment for real workpieces. The sensor 200 obtains, in real time, monitoring data relating to the plasma treatment apparatus 100 that is performing plasma treatment, and the workpieces. The monitoring data is stored in the fourth database. The first obtaining unit 300 obtains a first treatment mode including the number and the type of the real workpieces. The first treatment mode is stored in the first database. Thresholds corresponding to various treatment modes are stored in the second database. The determination unit 401 reads out the threshold corresponding to the obtained first treatment mode from the second database, and determines, based on the threshold and the monitoring data, whether or not there is an abnormality in the plasma treatment.

The determination unit 401 further determines whether or not the recipe needs to be modified, whether or not the threshold needs to be modified, whether or not a maintenance notification is needed, and whether or not a component needs to be ordered. The evaluation information relating to the real workpieces that has been obtained by the second obtaining unit 500 may be used for these determinations. If the recipe needs to be modified, a new recipe is generated by the calculation unit 403. The new recipe is stored in the third database. If the threshold needs to be modified, a new threshold is generated by the calculation unit 403. The new threshold is stored in the second database. If the maintenance is needed, the maintenance timing or the degree of progress of a defect is calculated by the calculation unit 403, and a replacement component is specified. The maintenance timing or the like is notified by the notification unit 600 to the manager of the server 400, or the owner or operator of the plasma treatment apparatus. The ordering unit 700 orders the replacement component from the manufacturer as needed.

### (A2) First Abnormality Determination Method

The abnormality determination method according to the present embodiment includes a plasma treatment step, a monitoring data obtaining step, and a determination step. The abnormality determination method according to the present embodiment is performed by the above-described first abnormality determination system. However, the abnormality determination method according to the present embodiment is not limited thereto.

In the following, the abnormality determination method according to the present embodiment will be described by dividing the abnormality determination method into mode A2-1 in which abnormality determination is performed in real time, mode A2-2 in which abnormality determination is performed after the plasma treatment has ended, and mode A2-3 and a mode A2-4 in which follow-up evaluation is further performed after abnormality determination.

### [Mode A2-1]

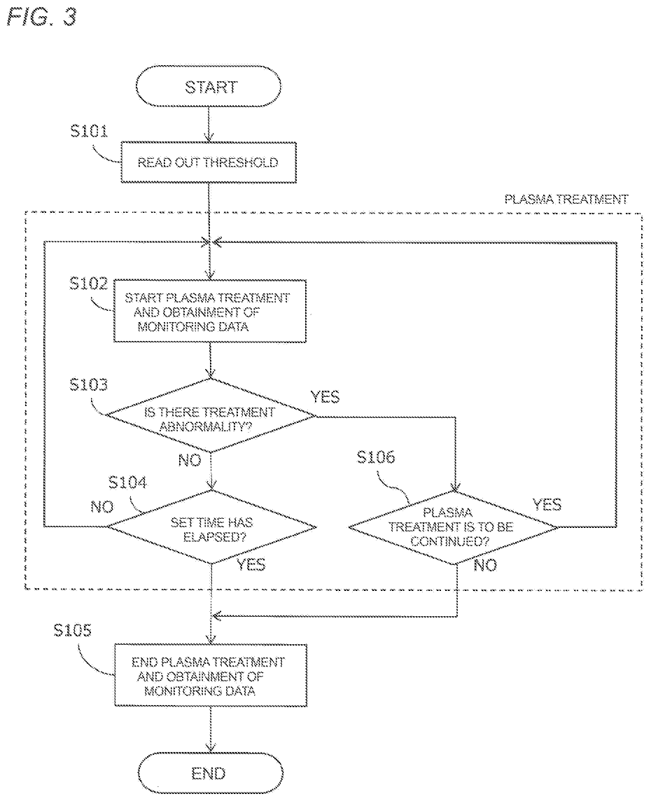

In the present embodiment, abnormality determination is performed in real time during treatment of real workpieces, and the result of determination is fed back to plasma treatment of the real workpieces that are being treated. Accordingly, the yield is increased. FIG. 3 is a flowchart showing an example of the abnormality determination method according to the present embodiment.

### (1) Plasma Treatment Step

First, a treatment mode relating to real workpieces is obtained by the obtaining unit, and is stored in the first database. The determination unit reads out a threshold from the second database (S101). Subsequently, the recipe corresponding to the treatment mode is read out from the third database, and plasma treatment based on the recipe is started (S102). The plasma treatment is performed in accordance with the flow shown in FIG. 1, for example.

### (2) Monitoring Data Obtaining Step

When the plasma treatment is started, obtainment of monitoring data by the sensor is started (S102). The monitoring data is stored in the fourth database. The type of the obtained monitoring data and the timing at which the monitoring data is obtained are shown in FIG. 1, for example. The obtainment of the monitoring data is performed until the plasma treatment ends.

The obtained monitoring data and the threshold are compared in real time (S103). The comparison of the monitoring data and the threshold is performed until the plasma treatment ends.

As a result of comparing the monitoring data and the threshold, if it is determined that there is no abnormality in the plasma treatment, the plasma treatment is continued as it is. Then, after a predetermined treatment time set in the recipe has elapsed (S104), the plasma treatment ends (S105). When the plasma treatment ends, the obtainment of the monitoring data also ends (S105).

On the other hand, if it is determined that there is an abnormality in the plasma treatment, the determination unit further determines whether or not to continue the plasma treatment (S106). If it is determined that the plasma treatment is to be continued, the plasma treatment is continued, and the obtainment of the monitoring data by the sensor (S102) and the comparison of the obtained monitoring data and the threshold (S103) are performed in the same manner as described above.

If it is determined that the plasma treatment is not to be continued, the plasma treatment ends (S105). Thereafter, whether or not maintenance of the apparatus is needed may be determined.

For example, as a result of comparing the monitoring data and the threshold, if the driving torque of the transport arm exceeds the threshold, the determination unit determines to stop the plasma treatment. After the plasma treatment has been stopped, a maintenance notification is provided by the notification unit so as to adjust the position of the transport rail. If the driving torque significantly varies, the determination unit also determines to stop the plasma treatment. In this case, a maintenance notification is provided so as to check the size and the shape of the workpieces, and contamination or the like, in addition to adjusting the position of the transport rail.

### [Mode A2-2]

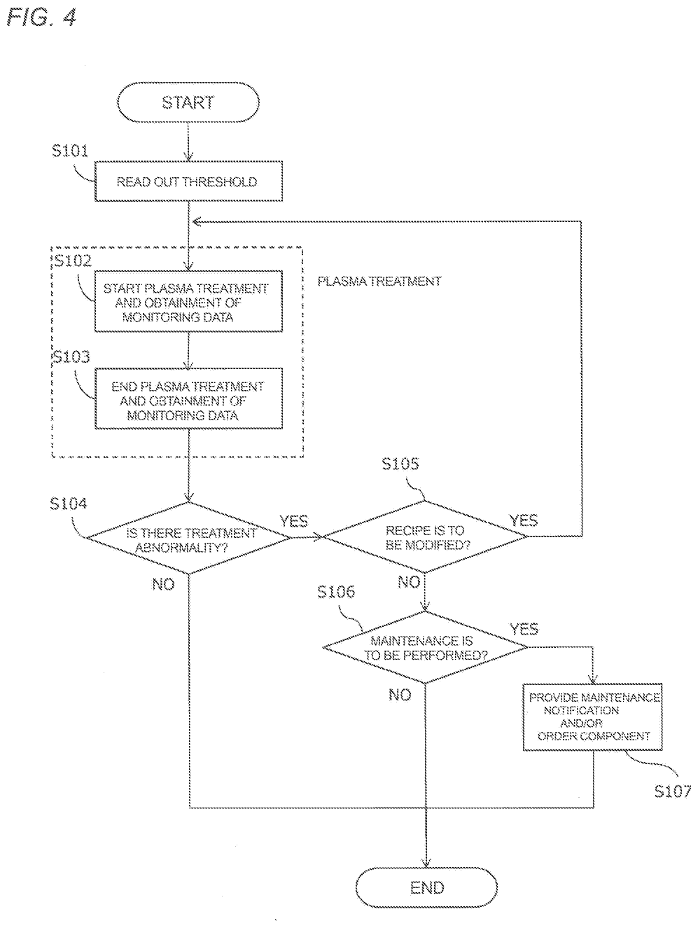

The present embodiment is the same as mode A2-1 except that abnormality determination is performed after the plasma treatment of the real workpieces has ended, and that the result of determination is fed back to the plasma treatment for workpieces subsequent to the real workpiece. In this case, it is possible to handle a variety of treatment abnormalities, so that the quality of plasma treatment is further improved. FIG. 4 is a flowchart showing an example of the abnormality determination method according to the present embodiment.

The obtained monitoring data is compared with the threshold after the plasma treatment has ended (S104). As a result of comparing the monitoring data and the threshold, if it is determined that there was no abnormality in the plasma treatment (determination in S104 is NO), the plasma treatment ends. On the other hand, if it is determined that there was a treatment abnormality (determination in S104 is YES), subsequently, whether or not the recipe needs to be modified (S105) and whether or not the maintenance is needed (S106) are sequentially determined. If the recipe is to be modified, a new recipe is fed back such that the plasma treatment for the subsequent workpieces is performed based on the new recipe. If the maintenance is to be performed, a maintenance notification is provided by the notification unit, and the replacement component is ordered as needed (S107).

For example, as a result of comparing the monitoring data and the threshold, if the evacuation speed is below the threshold, the determination unit can determine to provide a maintenance notification for the apparatus. In this case, the maintenance notification is provided so as to perform cleaning of the interior of the reaction chamber, checking of the operation of the evacuation pump, or the like. If the monitoring data relating to the discharge state falls outside the threshold, the maintenance notification is provided so as to perform checking of the operation of a component of the high-frequency power supply, the matching device, or the like.

### [Mode A2-3]

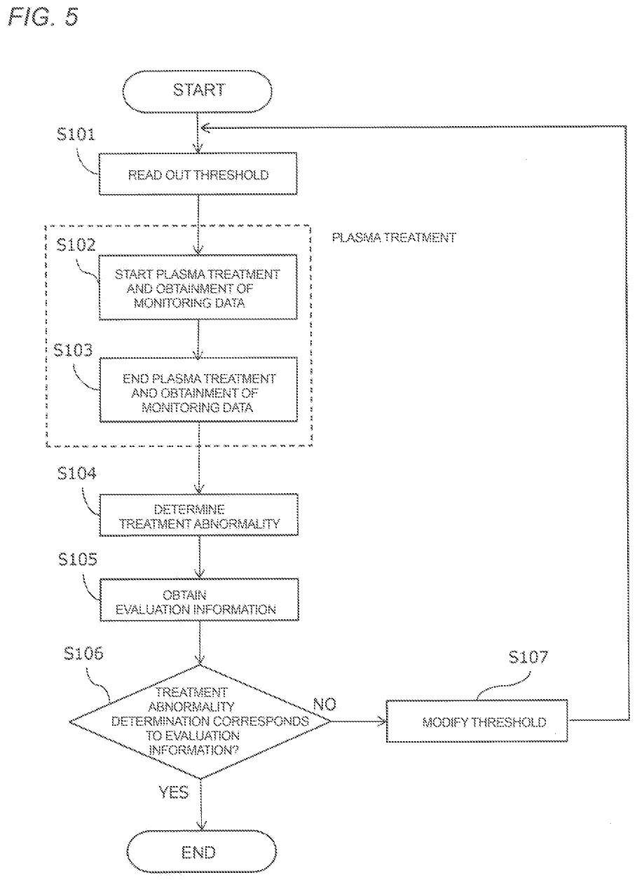

In the present embodiment, whether or not the abnormality determination was appropriate is checked taking the evaluation information into account. If the abnormality determination is inappropriate, the threshold is modified. This improves the accuracy of the abnormality determination. FIG. 5 is a flowchart showing an example of the abnormality determination method according to the present embodiment. The steps up to the abnormality determination are the same as those in mode A2-2.

After the abnormality determination (S104), the evaluation information is obtained (S105). Subsequently, whether or not the abnormality determination corresponds to the evaluation information is determined (S106). If it is determined in the abnormality determination that there is a treatment abnormality, and the actual treatment is also evaluated to be improper, it is determined that the abnormality determination corresponds to the evaluation information, and that the abnormality determination was appropriate.

On the other hand, if the actual treatment is evaluated to be proper despite that it is determined in the abnormality determination that there is a treatment abnormality, or, conversely, if the actual treatment is evaluated to be improper despite that it is determined in the abnormality determination that there is no treatment abnormality, the abnormality determination does not correspond to the evaluation information. That is, it is determined that the threshold used in the abnormality determination was inappropriate. In this case, the threshold is modified such that the abnormality determination corresponds to the evaluation information (S107). The modified threshold is fed back to the determination unit.

### [Mode A2-4]

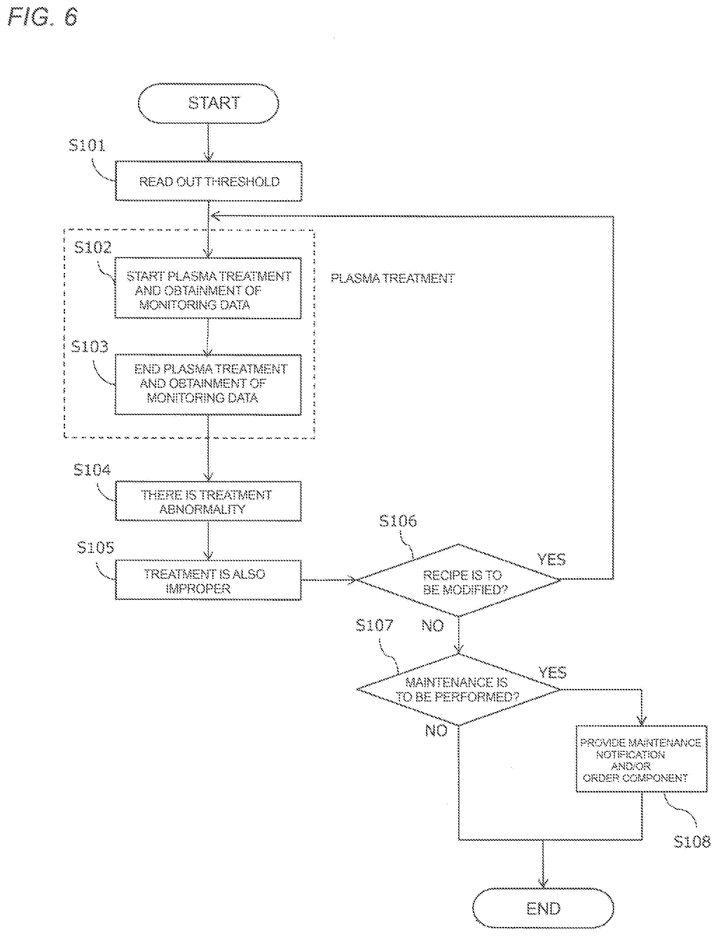

In the present embodiment, if it is determined that there is a treatment abnormality, and the actual treatment is also evaluated to be improper, whether or not the recipe needs to be modified, and whether or not a maintenance notification is needed are sequentially determined. The steps up to the abnormality determination are the same as those in mode A2-2 and mode A2-3. This allows for more appropriate treatment, so that the productivity is further increased. FIG. 6 is a flowchart showing an example of the abnormality determination method according to the present embodiment.

If it is determined that there is a treatment abnormality (S104), and the actual treatment is also evaluated to be improper (S105), whether or not the recipe needs to be modified (S106), and whether or not the maintenance is needed (S107) are sequentially determined. If the recipe is to be modified, a new recipe is fed back such that the plasma treatment for the subsequent workpieces is performed based on the new recipe. If maintenance is to be performed, a maintenance notification is provided by the notification unit, and a component is ordered as needed (S108).

### (B1) Second Abnormality Determination System

The abnormality determination system according to the present embodiment is the same as the first abnormality determination system except that whether or not there is an abnormality in plasma treatment is determined based on, in place of the threshold, a monitoring history relating to the plasma treatment apparatus and the workpieces that has been obtained by the sensor during plasma treatment performed in the past in the same mode as the first treatment mode.

That is, the second abnormality determination system includes: a plasma treatment apparatus capable of treating, based on a recipe, a plurality of workpieces at a time; a sensor that obtains at least one monitoring data relating to the workpieces and the plasma treatment apparatus that is performing plasma treatment; a storage unit that stores a monitoring history obtained by the sensor during plasma treatment performed in the past in a treatment mode that is the same as a first treatment mode including the number and the type of the workpieces to be plasma treated, the monitoring history corresponding to the monitoring data; and a determination unit that determines, based on a difference between the monitoring data and the monitoring history, whether or not there is an abnormality in the plasma treatment.

Monitoring histories corresponding to various treatment modes are stored in the storage unit. When the first treatment mode has been obtained, the calculation unit reads out the monitoring history corresponding to the first treatment mode from the storage unit, and calculates the difference from the monitoring data. If this difference is within the range of a preset tolerance, the determination unit determines that there is no treatment abnormality. On the other hand, if the above-described difference exceeds the preset tolerance, the determination unit determines that there is a treatment abnormality. The tolerance is set taking into account an evaluation history as to whether or not the past plasma treatment in the first treatment mode was proper. The tolerance may be stored in the storage unit.

Similarly to the first abnormality determination system, the determination unit can further determine in which of the plasma treatment apparatus, the workpieces, and the recipe the cause of the treatment abnormality lies. This determination is performed based on the type of monitoring data (hereinafter referred to as NG data) that exceeds the tolerance. The determination procedure is the same as that of the first abnormality determination system.

The causes of the treatment abnormality are further narrowed down by referring to the NG data and monitoring data (hereinafter referred to as OK data) that falls within the tolerance, or the reference history in the above-described second treatment mode. The narrowing down procedure is the same as that of the first abnormality determination system.

In addition, the determination unit may further determine whether or not to stop the plasma treatment, whether or not to modify the recipe, and whether or not to provide a maintenance notification. These determinations are performed based on the type of the NG data described above, and also on the evaluation information relating to the real workpieces. If the maintenance is needed, the maintenance timing or the degree of progression of a defect is calculated by the calculation unit, and a replacement component is specified.

The determination unit can further determine whether or not to modify the tolerance. Whether or not the tolerance needs to be modified is determined based on the evaluation information. For example, if the actual treatment is evaluated to be improper despite that it is determined that there is no treatment abnormality, the tolerance is modified so as to be narrower. Conversely, if the actual treatment is evaluated to be proper despite that it is determined that there is a treatment abnormality, the tolerance is modified to be wider. This reduces the frequency with which the apparatus is stopped as a result of abnormality determination, so that the operating ratio is increased, and the accuracy of the abnormality determination is further improved. The determination of the treatment abnormality is performed based on a new tolerance.

The second abnormality determination system has the same configuration as that of the first abnormality determination system shown in FIG. 2. That is, a second abnormality determination system 1000 includes a plasma treatment apparatus 100, a sensor 200, a first obtaining unit 300, a server 400, a second obtaining unit 500, a notification unit 600, and an ordering unit 700. The server 400 includes a determination unit 401, a storage unit 402, and a calculation unit 403. The storage unit 402 includes a first database in which treatment modes are stored, a third database in which recipes are stored, a fourth database in which monitoring data is stored, a fifth database in which evaluation information is stored, a sixth database in which monitoring histories are stored, and a seventh database in which tolerances are stored. The second abnormality determination system 1000 may further include a second database in which thresholds are stored.

The plasma treatment apparatus 100 performs, based on a recipe stored in the third database, plasma treatment for real workpieces. The sensor 200 obtains, in real time, monitoring data relating to the plasma treatment apparatus 100 that is performing the plasma treatment, and the workpieces. The monitoring data is stored in the fourth database. The first obtaining unit 300 obtains a treatment mode including the number and the type of the real workpieces. The treatment mode is stored in the first database.

When the treatment mode and the monitoring data have been obtained, the calculation unit 403 reads out the monitoring history corresponding to the obtained first treatment mode from the sixth database, and calculates the difference from the monitoring data. The determination unit 401 determines, based on the calculated difference, whether or not there is an abnormality in the plasma treatment. The tolerance taking into account the evaluation history is set for the calculated difference. If the difference is within the range of the tolerance, it is determined that there is no treatment abnormality.

The determination unit 401 further determines whether or not the recipe needs to be modified, whether or not the tolerance needs to be modified, whether or not the maintenance is needed, and whether or not a component needs to be ordered. The evaluation information relating to the real workpieces that has been obtained in the second obtaining unit 500 may be used for these determinations. If the recipe needs to be modified, a new recipe is generated by the calculation unit 403. The new recipe is stored in the third database. If the tolerance needs to be modified, a new tolerance is generated by the calculation unit 403. The new tolerance is stored in the seventh database. If the maintenance is needed, the maintenance timing or the degree of progression of a defect is calculated by the calculation unit 403, and a replacement component is specified. The maintenance timing or the like is also notified by the notification unit 600 to the manager of the server 400, or the owner or operator of the plasma treatment apparatus. The ordering unit 700 orders the replacement component from the manufacturer as needed.

### (B2) Second Abnormality Determination Method

The abnormality determination method according to the present embodiment is the same as the first abnormality determination system except that the abnormality determination is performed using, in place of the threshold, data (monitoring history) relating to the apparatus and the workpieces that has been obtained when plasma treating the workpieces in the same first treatment mode as that used for the real workpieces.

That is, the second abnormality determination method includes: a plasma treatment step of performing plasma treatment for workpieces, using a plasma treatment apparatus capable of treating a plurality of workpieces at a time; a monitoring data obtaining step of obtaining at least one monitoring data relating to the workpieces and the plasma treatment apparatus that is performing plasma treatment; a calculation step of calculating a difference between the monitoring data and a monitoring history obtained during plasma treatment performed in the past in a treatment mode that is the same as a first treatment mode including the number and the type of the workpieces to be plasma treated, the monitoring history corresponding to the monitoring data; and a determination step of determining, based on the difference, whether or not there is an abnormality in the plasma treatment.

The abnormality determination method according to the present embodiment is performed by the second abnormality determination system described above. However, the abnormality determination method according to the present embodiment is not limited thereto.

In the following, as in the case of the first abnormality determination method, the second abnormality determination method will be described by dividing the second abnormality determination method into mode B2-1 in which the abnormality determination is performed in real time, mode B2-2 in which the abnormality determination is performed after the plasma treatment has ended, and mode B2-3 and mode B2-4 in which follow-up evaluation is further performed after the abnormality determination.

### [Mode B2-1]

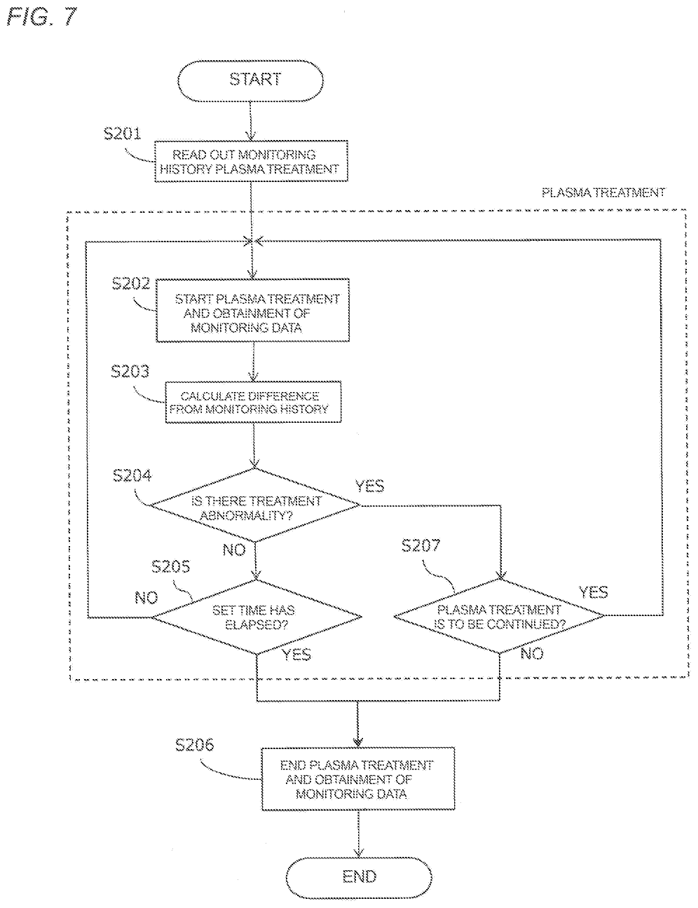

In the present embodiment, abnormality determination is performed in real time during treatment of real workpieces, and the result of determination is fed back to plasma treatment of the real workpieces that are being treated. Accordingly, the yield is increased. FIG. 7 is a flowchart showing an example of the abnormality determination method according to the present embodiment.

### (1) Plasma Treatment Step

First, a first treatment mode relating to the real workpieces is obtained by the obtaining unit, and is stored in the first database. The monitoring history corresponding to the first treatment mode is read out from the storage unit (S201). Subsequently, the recipe corresponding to the treatment mode is read out from the third database, and plasma treatment based on the recipe is started (S202). The plasma treatment is performed in accordance with the flow shown in FIG. 1, for example.

### (2) Monitoring Data Obtaining Step

When the plasma treatment is started, obtainment of monitoring data by the sensor is started (S202). The monitoring data is stored in the fourth database. The type of the obtained monitoring data and the timing at which the monitoring data is obtained are shown in FIG. 1, for example. The obtainment of the monitoring data is performed until the plasma treatment ends.

### (3) Calculation Step

The difference between the monitoring data relating to the real workpieces and the monitoring history is calculated (S203).

### (4) Determination Step

Whether or not the difference between the monitoring data and the monitoring history is within the range of a preset tolerance is checked in real time. The aforementioned checking is performed until the plasma treatment ends.

If the difference between the monitoring data and the monitoring history is within the range of the tolerance, it is determined that there is no abnormality in the plasma treatment (determined to be NO in S204), and the plasma treatment is continued as it is. Then, after a predetermined treatment time set in the recipe has elapsed (S205), the plasma treatment ends (S206). When the plasma treatment ends, the obtainment of the monitoring data also ends (S206).

On the other hand, if it is determined that there is an abnormality in the plasma treatment (determined to be YES in S204), the determination unit further determines whether or not to continue the plasma treatment (S207). If it is determined that the plasma treatment is to be continued, the plasma treatment is continued, and the obtainment of the monitoring data by the sensor (S202), the calculation (S203) and the checking (S204) of the difference between the obtained monitoring data and the monitoring history are performed in the same manner as described above.

If it is determined that the plasma treatment is not to be continued, the plasma treatment ends (S206). Thereafter, whether or not maintenance of the apparatus is needed may be determined.

### [Mode B2-2]

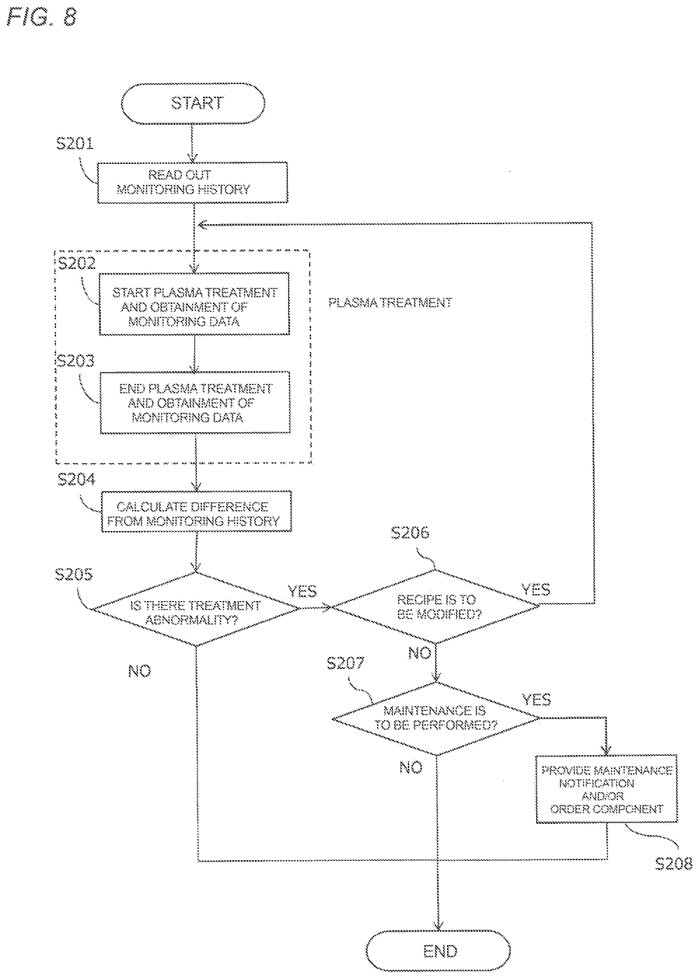

The present embodiment is the same as mode B2-1 except that the abnormality determination is performed after the plasma treatment of the real workpieces has ended, and that the result of determination is fed back to the plasma treatment for workpieces subsequent to the real workpieces. In this case, a variety of treatment abnormalities can be handled, so that the quality of the plasma treatment is further improved. FIG. 8 is a flowchart showing an example of the abnormality determination method according to the present embodiment.

The difference between the obtained monitoring data and the monitoring history is calculated after the plasma treatment has ended (S204). If the difference between the monitoring data and the monitoring history is within the range of the tolerance, it is determined that there was no abnormality in the plasma treatment (determination in S205 is NO), and the plasma treatment ends. On the other hand, if it is determined that there was a treatment abnormality (determination in S205 is YES), subsequently whether or not the recipe needs to be modified (S206), and whether or not the maintenance is needed (S207) are sequentially determined. If the recipe is to be modified, a new recipe is fed back such that the plasma treatment for the subsequent workpieces is performed based on the new recipe. If the maintenance is to be performed, a maintenance notification is provided by the notification unit, and the replacement component is ordered as needed (S208).

### [Mode B2-3]

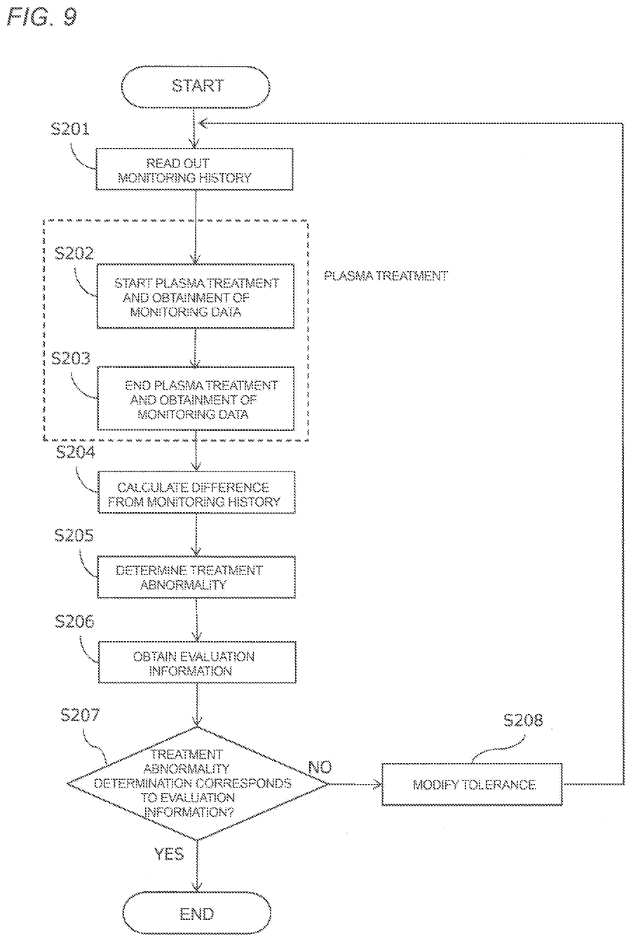

In the present embodiment, whether or not the abnormality determination was appropriate is checked taking the evaluation information into account. If the abnormality determination was inappropriate, the tolerance is modified. This improves the accuracy of the abnormality determination. The steps up to the abnormality determination are the same as those in mode B2-2. FIG. 9 is a flowchart showing an example of the abnormality determination method according to the present embodiment.

After the abnormality determination (S205), the evaluation information is obtained (S206). Subsequently, whether or not the abnormality determination corresponds to the evaluation information is determined (S207). If it is determined in the abnormality determination that there is a treatment abnormality, and the actual treatment is also evaluated to be improper, the abnormality determination corresponds to the evaluation information, so that it is determined that the abnormality determination was appropriate.

On the other hand, if the actual treatment is evaluated to be proper despite that it is determined in the abnormality determination that there is a treatment abnormality, and, conversely, if the actual treatment is evaluated to be improper despite that it is determined in the abnormality determination that there is no treatment abnormality, the abnormality determination does not correspond to the evaluation information. That is, it is determined that the tolerance used in the abnormality determination was in appropriate. In this case, the tolerance is modified (S208) such that the abnormality determination corresponds to the evaluation information. The modified tolerance is fed back to the determination unit.

### [Mode B2-4]

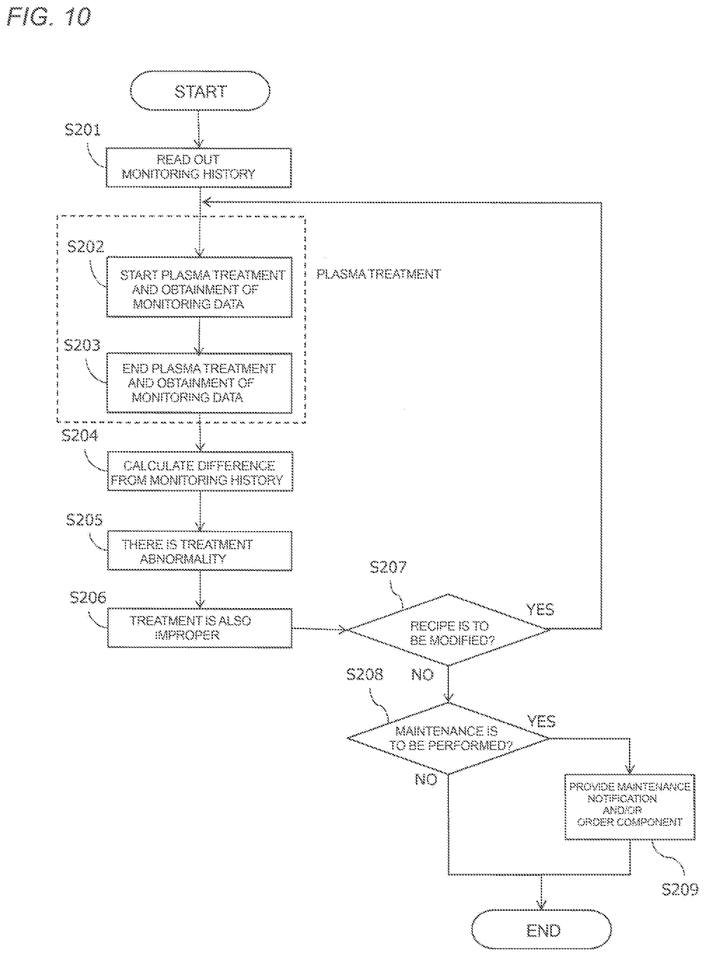

In the present embodiment, if it is determined that there is a treatment abnormality, and the actual treatment is also evaluated to be improper, whether or not the recipe needs to be modified and whether or not maintenance is needed are sequentially determined. This allows for more appropriate treatment, so that the productivity is further improved. The steps up to the abnormality determination are the same as those in mode B2-2 and mode B2-3. FIG. 10 is a flowchart showing an example of the abnormality determination method according to the present embodiment.

If it is determined that there is a treatment abnormality (S205), and the actual treatment is also evaluated to be improper (S206), whether the recipe needs to be modified (S207), and whether maintenance is needed (S208) are sequentially determined. If the recipe is to be modified, a new recipe is fed back such that the plasma treatment for the subsequent workpieces is performed based on the new recipe. If the maintenance is to be performed, a maintenance notification is provided by the notification unit, and a component is ordered as needed (S209).

Although the abnormality determination system and the abnormality determination method according to the embodiments of the present invention have been described above using specific modes, the abnormality determination system and the abnormality determination method according to the embodiments of the present invention are not limited thereto.

### INDUSTRIAL APPLICABILITY

With the abnormality determination system and the abnormality determination method according to the present invention, the quality of plasma treatment is improved. Accordingly, the abnormality determination system and the abnormality determination method according to the present invention can be suitably used for various plasma treatment apparatuses.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

### REFERENCE SIGNS LIST

1000 . . . . First abnormality determination system, second abnormality determination system
100 . . . . Plasma treatment apparatus
200 . . . . Sensor
300 . . . . First obtaining unit
400 . . . . Server
401 . . . . Determination unit
402 . . . . Storage unit
403 . . . . Calculation unit
500 . . . . Second obtaining unit
600 . . . . Notification unit
700 . . . . Ordering unit

What is claimed is:

1. An abnormality determination system for plasma treatment, comprising:
a plasma treatment apparatus capable of treating, based on a recipe, a plurality of workpieces at a time;
a sensor that obtains at least one monitoring data relating to the workpieces and the plasma treatment apparatus that is performing plasma treatment;
a storage unit that stores a threshold that is set according to a first treatment mode including the number and the type of the workpieces; and
a determination unit that determines, based on the monitoring data and the threshold, whether or not there is an abnormality in the plasma treatment.

2. The abnormality determination system for plasma treatment according to claim 1,
wherein if it is determined that there is an abnormality in the plasma treatment,
the determination unit further determines, based on the monitoring data that falls outside the threshold, whether or not the recipe needs to be modified.

3. The abnormality determination system for plasma treatment according to claim 1,
wherein if it is determined that there is an abnormality in the plasma treatment,
the determination unit further determines, based on the monitoring data that falls outside the threshold, whether or not maintenance of the plasma treatment apparatus is needed.

4. The abnormality determination system for plasma treatment according to claim 3,
further comprising a notification unit,
wherein if the maintenance is needed, the notification unit provides a notification to perform maintenance of the plasma treatment apparatus.

5. The abnormality determination system for plasma treatment according to claim 3,
further comprising an ordering unit,
wherein if the maintenance is needed, the ordering unit orders a component of the plasma treatment apparatus that has caused the abnormality.

6. The abnormality determination system for plasma treatment according to claim 1,
wherein if it is determined that there is an abnormality in the plasma treatment,
the determination unit further determines, based on the monitoring data that falls outside the threshold, whether or not to stop the plasma treatment.

7. The abnormality determination system for plasma treatment according to claim 1,
wherein if it is determined that there is an abnormality in the plasma treatment,
the determination unit further determines whether or not a cause of the abnormality of the plasma treatment lies in the workpieces, based on the monitoring data that falls outside the threshold, and a reference history obtained by the sensor during plasma treatment performed in the past in a second treatment mode that is different from the first treatment mode in the number of workpieces, the reference history corresponding to the monitoring data.

8. The abnormality determination system for plasma treatment according to claim 1,
further comprising an obtaining unit that obtains, after the plasma treatment, evaluation information as to whether the plasma treatment for the workpieces was proper.

9. The abnormality determination system for plasma treatment according to claim 8,
wherein the determination unit further determines, based on the evaluation information, whether or not the threshold needs to be modified.

10. An abnormality determination system for plasma treatment, comprising:
a plasma treatment apparatus capable of treating, based on a recipe, a plurality of workpieces at a time;
a sensor that obtains at least one monitoring data relating to the workpieces and the plasma treatment apparatus that is performing plasma treatment;
a storage unit that stores a monitoring history obtained by the sensor during plasma treatment performed in the past in a treatment mode that is the same as a first treatment mode including the number and the type of the workpieces to be plasma treated, the monitoring history corresponding to the monitoring data; and
a determination unit that determines, based on a difference between the monitoring data and the monitoring history, whether or not there is an abnormality in the plasma treatment.

11. The abnormality determination system for plasma treatment according to claim 10,
wherein if it is determined that there is an abnormality in the plasma treatment,
the determination unit further determines, based on the monitoring data that exceeds a tolerance that is preset for the difference, whether or not the recipe needs to be modified.

12. The abnormality determination system for plasma treatment according to claim 10,
wherein if it is determined that there is an abnormality in the plasma treatment,
the determination unit further determines, based on the monitoring data that exceeds a tolerance that is preset for the difference, whether or not maintenance of the plasma treatment apparatus is needed.

13. The abnormality determination system for plasma treatment according to claim 12,
further comprising a notification unit,
wherein if the maintenance is needed, the notification unit provides a notification to perform maintenance of the plasma treatment apparatus.

14. The abnormality determination system for plasma treatment according to claim 12,
further comprising an ordering unit,
wherein if the maintenance is needed, the ordering unit orders a component of the plasma treatment apparatus that has caused the abnormality.

15. The abnormality determination system for plasma treatment according to claim 10,
wherein if it is determined that there is an abnormality in the plasma treatment,
the determination unit further determines, based on the monitoring data that exceeds a tolerance that is preset for the difference, whether or not to stop the plasma treatment.

16. The abnormality determination system for plasma treatment according to claim 10,
wherein if it is determined that there is an abnormality in the plasma treatment,
the determination unit further determines whether or not a cause of the abnormality of the plasma treatment lies in the workpieces, based on the monitoring data that exceeds a tolerance that is preset for the difference, and a reference history obtained by the sensor during plasma treatment performed in the past in a second treatment mode that is different from the first treatment mode in the number of workpieces, the reference history corresponding to the monitoring data.

17. The abnormality determination system for plasma treatment according to claim 10,
further comprising an obtaining unit that obtains, after the plasma treatment, evaluation information as to whether the plasma treatment for the workpieces was proper.

18. The abnormality determination system for plasma treatment according to claim 17,
wherein the determination unit further determines, based on the evaluation information, whether or not a tolerance that is preset for the difference needs to be modified.

19. An abnormality determination method for plasma treatment, comprising:
a plasma treatment step of performing plasma treatment for workpieces, using a plasma treatment apparatus capable of treating a plurality of workpieces at a time;
a monitoring data obtaining step of obtaining at least one monitoring data relating to the workpieces and the plasma treatment apparatus that is performing plasma treatment; and
a determination step of determining whether or not there is an abnormality in the plasma treatment, based on the monitoring data, and a threshold that is set according to a first treatment mode including the number and the type of the workpieces.

20. An abnormality determination method for plasma treatment, comprising:
a plasma treatment step of performing plasma treatment for workpieces, using a plasma treatment apparatus capable of treating a plurality of workpieces at a time;
a monitoring data obtaining step of obtaining at least one monitoring data relating to the workpieces and the plasma treatment apparatus that is performing plasma treatment;
a calculation step of calculating a difference between the monitoring data and a monitoring history obtained during plasma treatment performed in the past in a treatment mode that is the same as a first treatment mode including the number and the type of the workpieces to be plasma treated, the monitoring history corresponding to the monitoring data; and
a determination step of determining, based on the difference, whether or not there is an abnormality in the plasma treatment.
